(19) United States
(12) Patent Application Publication
(10) Pub. No.: US 2012/0289019 A1
(43) Pub. Date: Nov. 15, 2012

(54) METHODS OF FORMING A PATTERN AND METHODS OF MANUFACTURING A SEMICONDUCTOR DEVICE USING THE SAME

(75) Inventors: Dong-Hyun Im, Hwaseong-si (KR); Byoung-Jae Bae, Hwaseong-si (KR); Young-Jae Kim, Yongin-si (KR); Dae-Keun Kang, Yeonsu-gu (KR)

(73) Assignee: Samsung Electronics Co., Ltd.

(21) Appl. No.: 13/467,734

(22) Filed: May 9, 2012

(30) Foreign Application Priority Data
May 11, 2011 (KR) 10-2011-0043871

(51) Int. Cl. H01L 21/02; H01L 21/283

(52) U.S. Cl. 438/381; 438/669; 257/E21.003; 257/E21.159

(57) ABSTRACT

In a method of forming a pattern, a plurality of first line patterns and first spacers filling spaces between the adjacent first line patterns are formed on an object layer. The first line patterns and the first spacers extend in a first direction. A plurality of second line patterns are formed on the first line patterns and the first spacers. The second line patterns extend in a second direction substantially perpendicular to the first direction. The first spacers are partially removed by a wet etching process. The object layer is etched using the first and second line patterns as an etching mask.

### REFERENCE TO PRIORITY APPLICATION

This application claims priority under 35 USC §119 to Korean Patent Application No. 10-2011-0043871, filed May 11, 2011, the disclosure of which is hereby incorporated herein by reference.

### FIELD

Example embodiments relate to methods of forming a pattern and methods of manufacturing a semiconductor device using the same.

### BACKGROUND

As semiconductor devices have been highly integrated, fine line width contact holes having small contact openings may be required. To form contact holes having small contact openings, a double patterning process (DPT) may be utilized to compensate for the relatively limited resolution of even state-of-the-art exposure and/or photolithography apparatus. However, as an aspect ratio of a contact hole within an insulating layer increases, an etching depth of the contact hole may increase. In addition, an etching mask that may be used in a DPT process may be etched and damage may be caused to the etching mask.

### SUMMARY

Example embodiments provide methods of forming a pattern having contact holes with fine line width. and high aspect ratio.

Example embodiments provide methods of manufacturing a semiconductor device using the method of forming the pattern.

According to example embodiments, there is provided a method of forming a pattern. In the method, a plurality of first line patterns and first spacers filling spaces between the adjacent first line patterns may be formed on an object layer. The first line patterns and the first spacers may extend in a first direction. A plurality of second line patterns may be formed on the first line patterns and the first spacers. The second line patterns may extend in a second direction substantially perpendicular to the first direction. The first spacers may be removed by a wet etching process. The object layer may be etched using the first and second line patterns as an etching mask.

In example embodiments, the first and second line patterns may be formed using polysilicon. The first spacers may be formed using silicon oxide.

In example embodiments, the object layer may be etched by a dry etching process.

In example embodiments, the first line patterns may include first polysilicon patterns and second polysilicon patterns extending in the first direction.

In example embodiments, in the formation of the first line patterns, a plurality of the first polysilicon patterns extending in the first direction may be formed on the object layer. The first spacers may be formed on sidewalls of the first polysilicon patterns. The second polysilicon patterns may be formed on the object layer. The second polysilicon patterns may fill spaces between the adjacent first spacers.

In example embodiments, the second polysilicon patterns may be self-aligned with the first spacers.

In example embodiments, the first polysilicon pattern, the first spacer and the second polysilicon pattern may have the same line width as one another.

In example embodiments, in the formation of the second line patterns, a plurality of first polysilicon patterns extending in the first direction may be formed on the object layer. The first spacers may be formed on sidewalls of the first polysilicon patterns. A second polysilicon layer may be formed on the first polysilicon patterns, the first spacers and the object layer. The second polysilicon layer may fill spaces between the adjacent first spacers. The second polysilicon layer may be etched to form the second line patterns extending in the second direction.

In example embodiments, in etching the second polysilicon layer to form the second line patterns, a plurality of mask patterns may be formed on the second polysilicon layer. The mask patterns may extend in the second direction. Second spacers may be formed on sidewalls of the mask patterns. The mask patterns may be removed. The second polysilicon layer may be etched using the second spacers as an etching mask until the first spacers are exposed.

In example embodiments, the mask pattern, the second spacer and the second line pattern may have the same line width as one another.

In example embodiments, the mask pattern may include silicon-based spin on hard mask (Si-SOH).

According to example embodiments, there is provided a method of manufacturing a semiconductor device. In the method, a first insulating interlayer may be formed on a substrate including an impurity region. The first insulating interlayer may be partially etched to form a plurality of first contact holes. A P-N diode filling each of the first contact holes may be formed. In the formation of the first contact holes, a plurality of first line patterns and first spacers filling spaces between the adjacent first line patterns may be formed on the first insulating interlayer. The first line patterns and the first spacers may extend in a first direction. A plurality of second line patterns may be formed on the first line patterns and the first spacers. The second line patterns may extend in a second direction substantially perpendicular to the first direction. The first spacers may be removed by a wet etching process. The first insulating interlayer may be partially etched using the first and second line patterns as an etching mask.

In example embodiments, a second insulating interlayer may be formed on the first insulating interlayer and the P-N diode. The second insulating interlayer may be partially etched to form a plurality of second contact holes. Each of the second contact holes may expose the P-N diode. A heating contact filling the second contact hole may be formed. A phase change layer pattern and an upper electrode may be formed sequentially on the heating contact and the second insulating interlayer. In the formation of the second contact holes, a plurality of third line patterns and second spacers filling spaces between the adjacent third line patterns may be formed on the second insulating interlayer. The third line patterns and the second spacers may extend in a third direction. A plurality of fourth line patterns may be formed on the third line patterns and the second spacers. The fourth line patterns may extend in a fourth direction substantially perpendicular to the third direction. The second spacers may be removed by a wet etching process. The second insulating interlayer may be partially etched using the third and fourth line patterns as an etching mask.

In example embodiments, the first and second line patterns may be formed using polysilicon, and the first spacers may be formed using silicon oxide.

According to example embodiments, there is provided a method of manufacturing a semiconductor device. In the method, a first plurality of stripe-shaped line patterns may be formed at side-by-side locations on an insulating interlayer. First stripe-shaped spacers may be formed on opposing sidewalls of the first plurality of stripe-shaped line patterns. The first stripe-shaped spacers may fill spaces between the first plurality of stripe-shaped line patterns. A second plurality of stripe-shaped line patterns may be formed at side-by-side locations on the first plurality of stripe-shaped line patterns and the first stripe-shaped spacers. The second plurality of stripe-shaped line patterns may extend in a direction orthogonal to a direction of the first plurality of stripe-shaped line patterns and the first stripe-shaped spacers. Portions of the first stripe-shaped spacers exposed between the first and second pluralities of stripe-shaped line patterns may be removed by a wet etching process to thereby expose portions of the insulating interlayer. Contact openings may be formed in the insulating interlayer by selectively etching the insulating interlayer using the first and second pluralities of stripe-shaped line patterns as an etching mask.

In example embodiments, the first and second pluralities of stripe-shaped line patterns may comprise polysilicon.

In example embodiments, forming the contact openings may comprise forming a two-dimensional array of equivalently sized contact openings in the insulating interlayer.

In example embodiments, the semiconductor device may be a nonvolatile memory device comprising phase change memory cells therein. Forming the first plurality of stripe-shaped line patterns may be preceded by forming the insulating interlayer on an underlying insulation layer having an array of P-N junction diodes therein.

In example embodiments, the array of P-N junction diodes may be formed by epitaxially growing semiconductor regions within openings in the underlying insulation layer.

### BRIEF DESCRIPTION OF THE DRAWINGS

Example embodiments will be more clearly understood from the following detailed description taken in conjunction with the accompanying drawings. FIGS. 1 to 26 represent non-limiting, example embodiments as described herein.

FIGS. 1 to 10 are cross-sectional, top and perspective views illustrating a method of forming a pattern in accordance with example embodiments.

FIGS. 11 to 18 are cross-sectional views illustrating a method of manufacturing a semiconductor device in accordance with example embodiments;

FIGS. 19 to 22 are cross-sectional views illustrating a method of manufacturing a semiconductor device in accordance with some example embodiments; and

FIGS. 23 to 26 are cross-sectional views illustrating a method of manufacturing a semiconductor device in accordance with example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, example embodiments will be explained in detail with reference to the accompanying drawings.

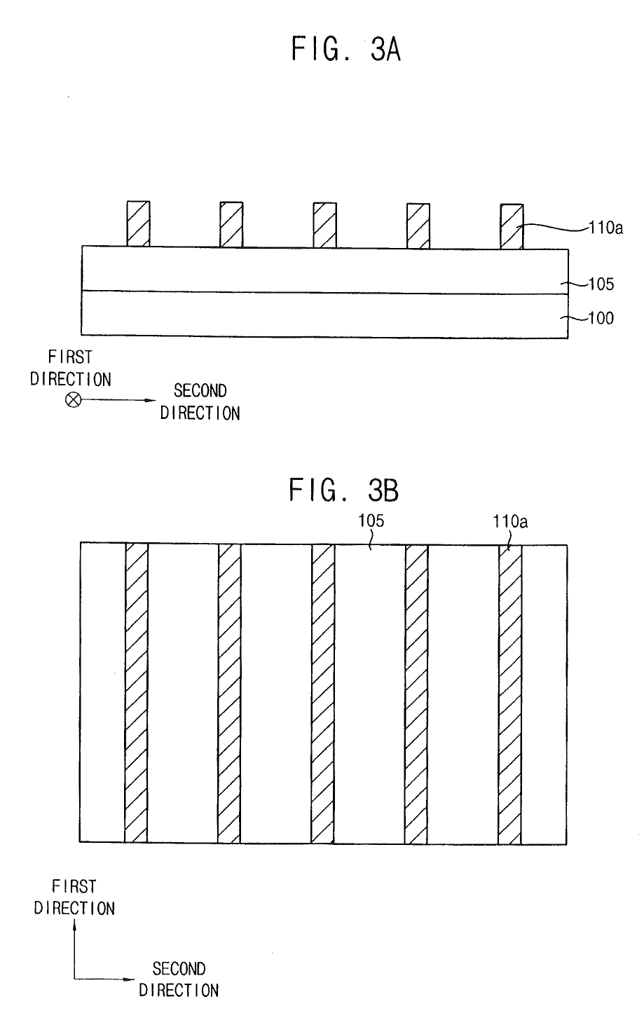

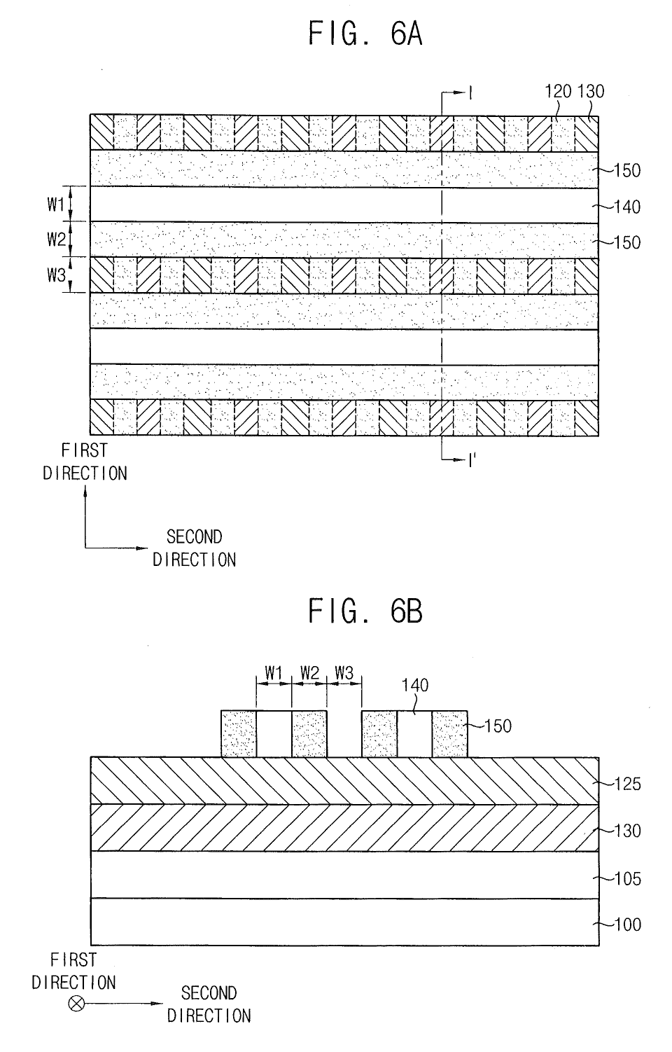

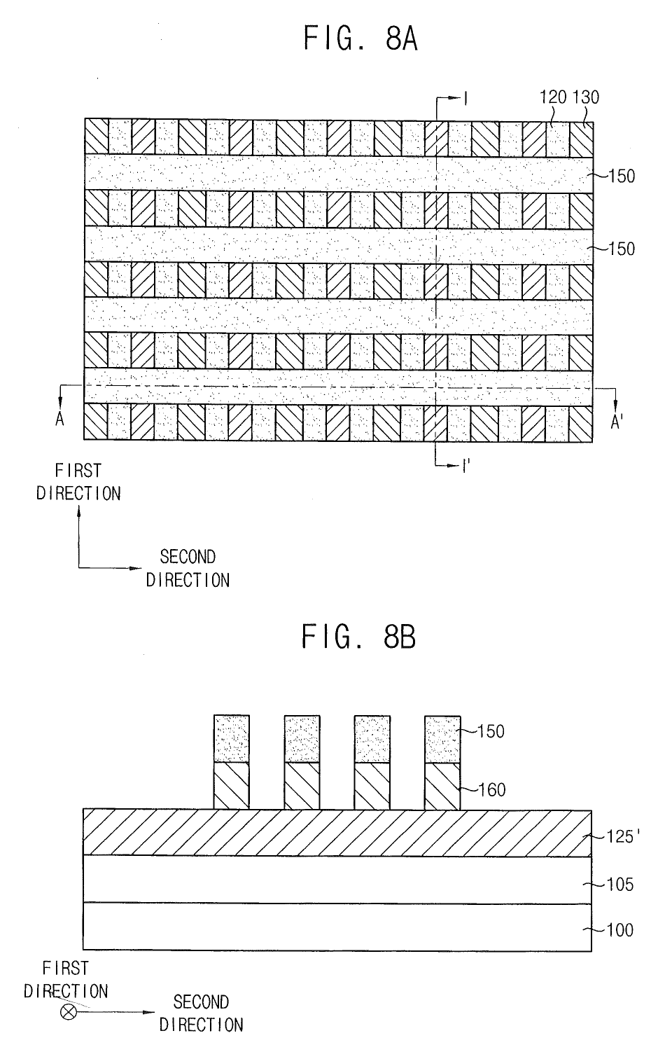

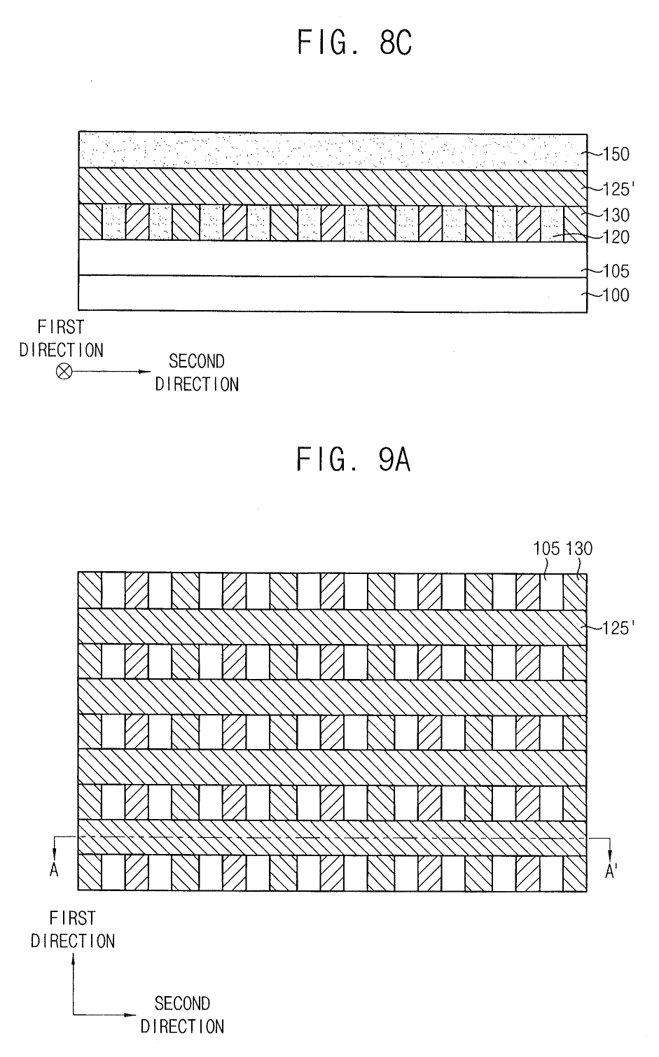

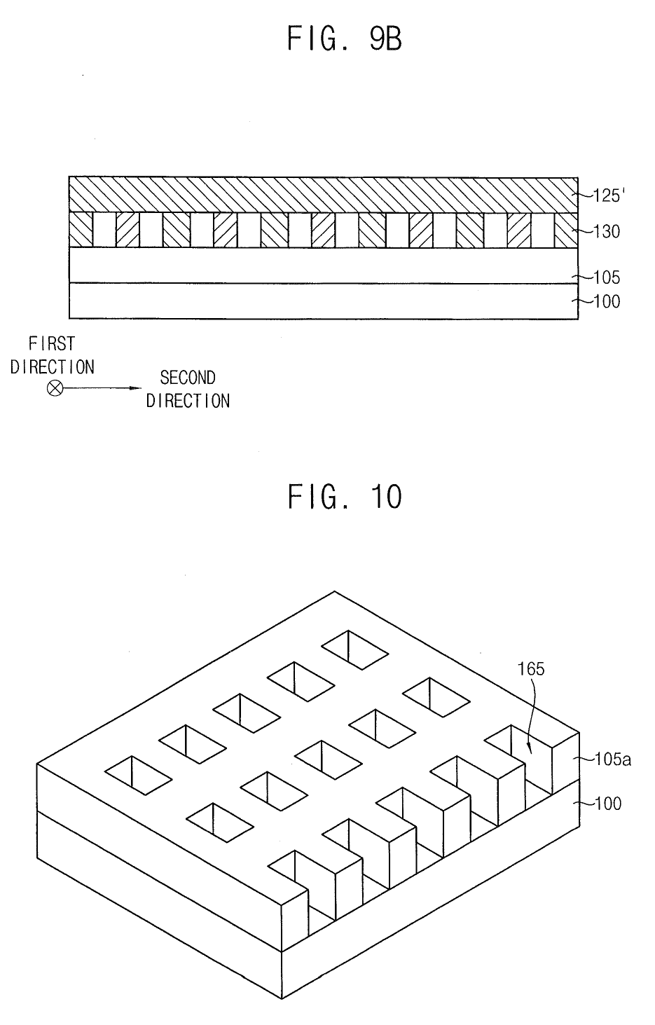

FIGS. 1 to 10 are cross-sectional, top and perspective views illustrating a method of forming a pattern in accordance with example embodiments. Specifically, FIGS. 1, 2, 3A, 4A and 5A are cross-sectional views illustrating the method of forming the pattern in accordance with example embodiments. FIGS. 3B, 4B, 5B, 6A, 7A, 8A and 9A are top views illustrating the method of forming the pattern in accordance with example embodiments. FIGS. 6B, 7B and 8B are cross-sectional views taken along I-J′ lines of FIGS. 6A, 7A and 8A, respectively. FIGS. 8C and 9B are cross-sectional views taken along A-A′ lines of FIGS. 8A and 9A, respectively. FIG. 10 is a perspective view illustrating a resultant pattern in accordance with example embodiments.

Referring to FIG. 1, an object layer 105, a first polysilicon layer 110 and a first mask layer 115 may be sequentially formed on a substrate 100. The substrate 100 may include a semiconductor substrate. For example, the substrate 100 may include a silicon substrate, a germanium substrate, a silicon-germanium substrate, a silicon-on-insulator (SOI) substrate, a germanium-on-insulator (GOI) substrate, etc. Additional structures (not illustrated) may be formed on the substrate 100. For example, the additional structures may include a conductive structure (not illustrated) including a metal, a metal nitride, a metal silicide, etc., or an insulation layer (not illustrated). The conductive structure may include a conductive layer or an electrode, for example.

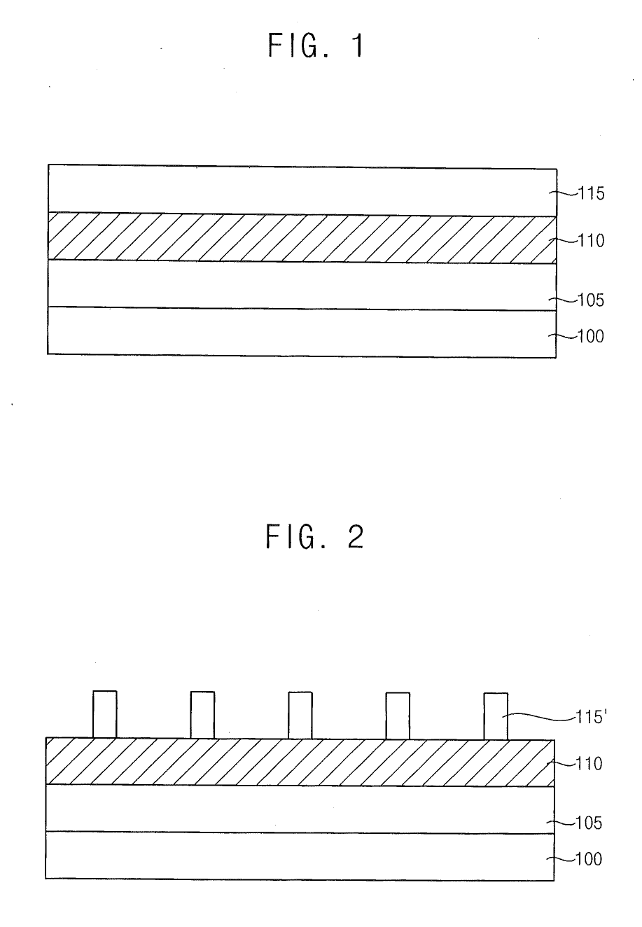

The object layer 105 may be formed using silicon nitride or an oxide such as phosphor silicate glass (PSG), boro-phosphor silicate glass (BPSG), undoped silicate glass (USG), tetra ethyl ortho silicate (TEOS), plasma enhanced-TEOS (PE-TEOS) or high density plasma-chemical vapor deposition (HDP-CVD) oxide. The object layer 105 may be obtained by a chemical vapor deposition (CVD) process, a plasma enhanced chemical vapor deposition (PECVD) process, a spin coating (spin coating) process, an HDP-CVD process, etc. The first polysilicon layer 110 may be formed using a CVD process or a sputtering process, for example. The first mask layer 115 may be formed as a silicon-based spin-on hard mask (Si-SOH), e.g., a spin-on glass (SOG) layer. In one example embodiment, an anti-reflective layer (not illustrated) may be further formed on the first mask layer 115. The anti-reflective layer may be formed as a silicon oxynitride (SiON) layer, for example, using a CVD deposition process. Referring to FIG. 2, photoresist patterns (not illustrated) may be formed on the first mask layer 115. The first mask layer 115 may be partially removed using the photoresist patterns as an etching mask to thereby form a plurality of first mask patterns 115′.

Referring to FIGS. 3A and 3B, the first polysilicon layer 110 may be patterned using the first mask patterns 115′ as an etching mask to thereby form a first polysilicon pattern 110a. In example embodiments, a plurality of the first polysilicon patterns 110a may be formed as parallel stripes positioned at side by side locations along a second direction. Each of the first polysilicon patterns 110a may extend in a first direction substantially perpendicular to the second direction. The photoresist pattern and the first mask pattern 115′ may be removed by an aching process and/or a strip process.

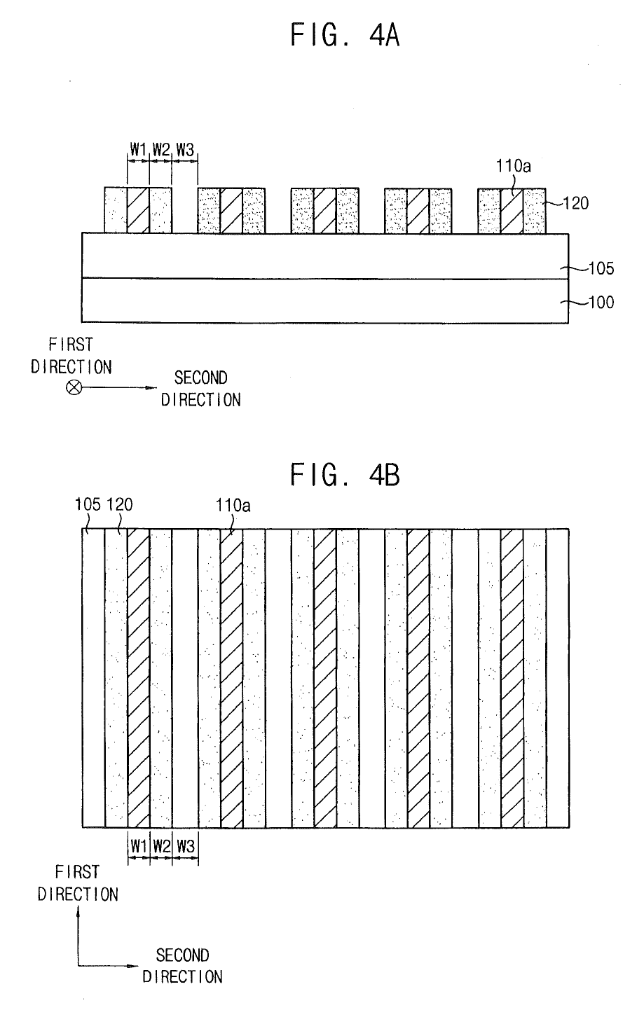

Referring to FIGS. 4A and 4B, first spacers 120 may be formed on sidewalls of the first polysilicon patterns 110a. For example, a first spacer layer may be formed on the object layer 105 to cover the first polysilicon patterns 110a. The first spacer layer may be partially removed by an etch-back process to form the first spacers 120 on the sidewalls of the first polysilicon patterns 110a. In example embodiments, the first spacer layer may be formed using silicon oxide, such as a middle temperature oxide (MTO), high temperature oxide (HTO) or atomic layer deposition (ALD) oxide. In example embodiments, a line width of the first polysilicon pattern 110a (W1), a line width of the first spacer 120 (W2) and a width between the adjacent first spacers 110a (W3) may be substantially equal.

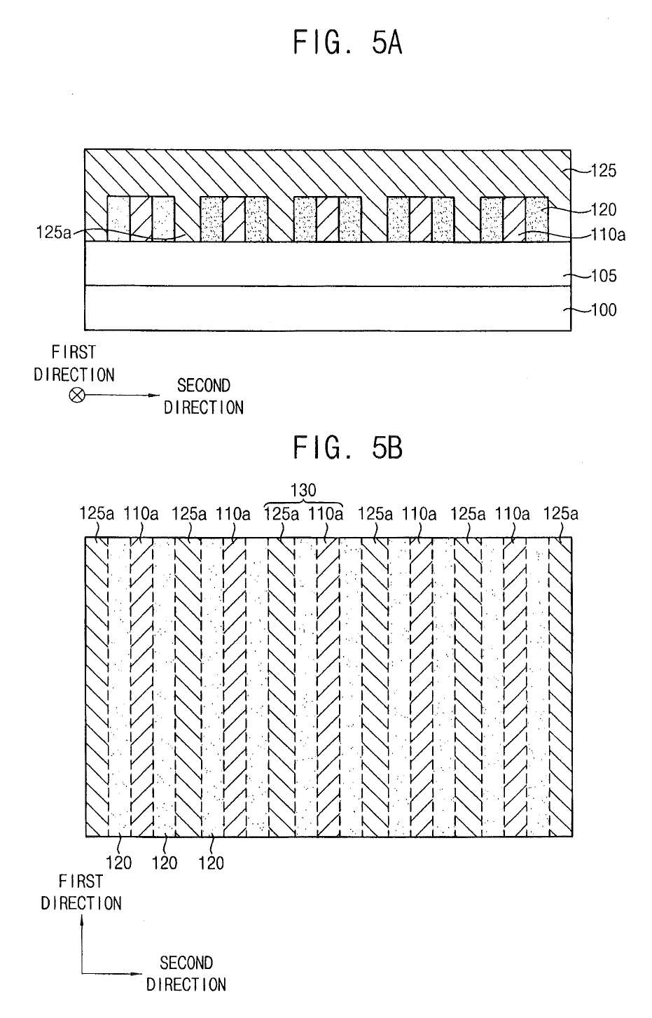

Referring to FIGS. 5A and 5B, a second polysilicon layer 125 may be formed on the object layer 105 to cover the first polysilicon patterns 110a and the first spacers 120. Here, a portion of the second polysilicon layer filling a space between the adjacent first spacers 120 may be defined as stripe-shaped second polysilicon patterns 125a. That is, a plurality of the second polysilicon patterns 125a may be formed along the second direction and each of the second polysilicon patterns 125a may extend in the first direction. In example embodiments, the second polysilicon patterns 125a may have a line width substantially the same as that of the first polysilicon patterns 110a.

The first polysilicon patterns 110a, the second polysilicon patterns 125a and the first spacers 120 beneath the second polysilicon layer 125 are indicated by dashed lines in FIG. 5B. First line patterns 130 including the first and second polysilicon patterns 110a and 125a may be defined by forming the second polysilicon patterns 125a. In example embodiments, the first line patterns 130 may be formed by a self-aligned double patterning (SADP) process. That is, the second polysilicon patterns 125a of the first line patterns 130 may be self-aligned with the first spacers 120.

Referring to FIGS. 6A and 6B, second mask patterns 140 extending in the second direction may be formed on the second polysilicon layer 125 and second spacers 150 may be formed on sidewalls of the second mask patterns 140. In example embodiments, a second mask layer may be formed on the second polysilicon layer 125, and then photoresist patterns (not illustrated), which may extend in the second direction, may be formed on the second mask layer. The second mask layer may be formed as a Si-SOH layer, such as SOG. In one example embodiment, an anti-reflective layer may be further formed on the second mask layer The second mask layer may be partially removed using the photoresist patterns as an etching mask to form the second mask patterns 140. The photoresist patterns may be removed using an ashing process and/or a strip process, for example.

A second spacer layer covering the second mask patterns 140 may be formed on the second polysilicon layer 125. The second spacer layer may be partially removed by an etch-back process to form the second spacers 150 on the sidewalls of the second mask patterns 140. In example embodiments, the second spacer layer may be formed using silicon oxide, such as an MTO, HTO or ALD oxide. A line width of the second mask pattern 140 (W1), a line width of the second spacer 150 (W2) and a width between the adjacent second spacers 150 (W3) may be substantially equal.

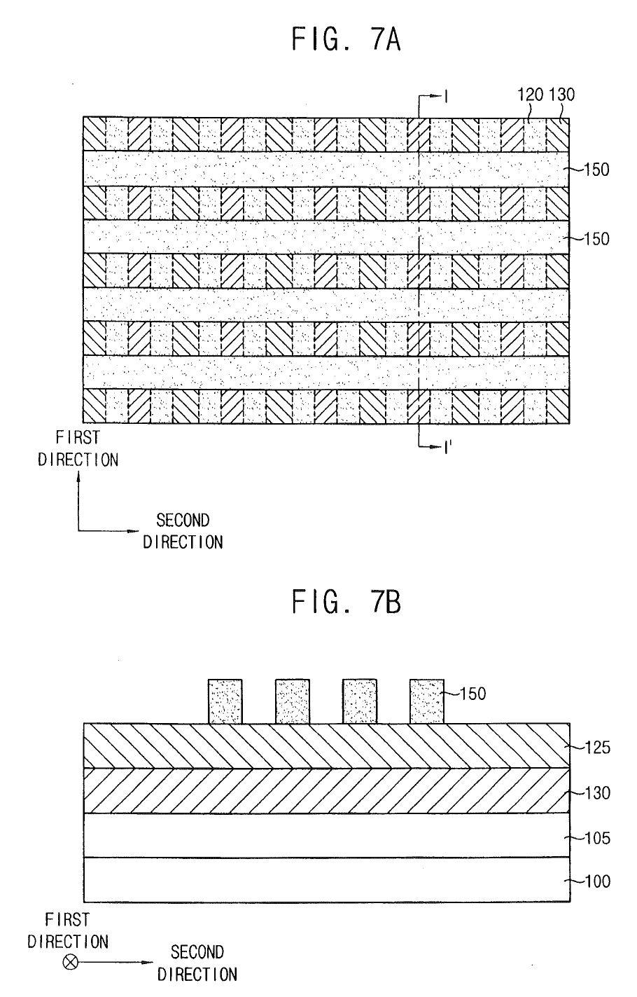

Referring to FIGS. 7A and 7B, the second mask patterns 140 may be removed by an ashing process to expose a top surface of the second polysilicon layer 125 between the adjacent second spacers 150. Referring to FIGS. 8A-8C, the second polysilicon layer 125 may be partially removed using the second spacers 150 as an etching mask to form second line patterns 125′. Each of the second line patterns 125′ may extend in the second direction. Accordingly, top surfaces of the first spacers 120 and the first line patterns 130 may be partially exposed between the adjacent second line patterns 125′. When the second polysilicon layer 125 is etched, upper portions of the first line patterns 130 may be also partially removed. The second spacers 150 may be removed by an ashing process and/or a strip process.

As described above, the second line patterns 125′ may be formed by a self-aligned reverse patterning (SARP) process. That is, the second mask patterns 140 between the second spacers 150 may be removed, and then the second polysilicon layer 125 may be etched using the second spacers 150 as the etching mask to form the second line patterns 125′.

Referring to FIGS. 9A-9B, the first spacers 120 exposed between the first line patterns 130 and the second line patterns 125′ crossing over the first line patterns 130 may be removed. In example embodiments, at least portions of the first spacers 120 may be removed by a wet etching process in which an etching solution having an etching selectivity for silicon oxide may be used. For example, the etching solution may include hydrofluoric acid (HF) or a buffer oxide etchant (BOE) solution. By removing the first spacers 120, a top surface of the objective layer 105 may be exposed between the first and second line patterns 130 and 125′.

Referring to FIG. 10, the objective layer 105 may be etched using the first and second line patterns 130 and 125′ as an etching mask to form an objective layer pattern 105a. The objective layer pattern 105a may include a plurality of contact holes 165 therein. A top surface of the substrate 100 may be exposed by the contact holes 165. In example embodiments, the contact holes 165 may be formed by a dry etching process. The first and second line patterns 130 and 125′ may be removed using a chemical mechanical polishing (CMP) process or an etch-back process, for example.

According to example embodiments, to form the contact holes 165, the first spacers 120 may be removed by a wet etching process, and then the objective layer 105 may be etched by a dry etching process. When only a dry etching process is performed to form the contact holes 165, the first and second line patterns 130 and 125′ (hereinafter, referred to as an etching mask) may be also etched and damage may be caused therein. When the contact holes 165 have a very large aspect ratio, the damage to the etching mask may be more worsened. However, in example embodiments, both a wet etching process and a dry etching process may be utilized to form the contact holes 165 while minimizing damage to the etching mask.

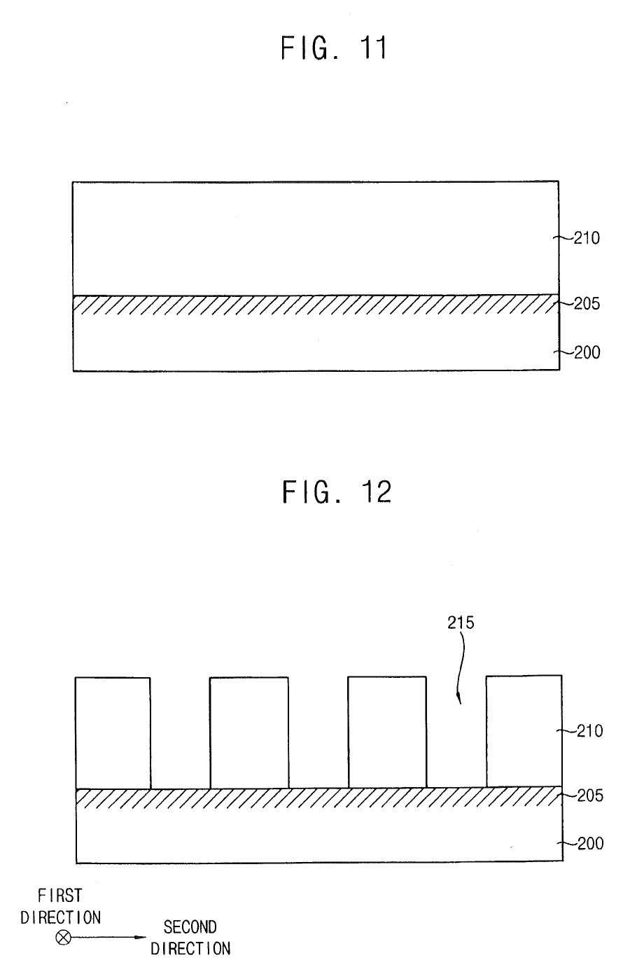

FIGS. 11 to 18 are cross-sectional views illustrating a method of manufacturing a semiconductor device in accordance with example embodiments. Specifically, FIGS. 11-18 are cross-sectional views illustrating a method of manufacturing a phase change memory device. Referring to FIG. 11, a first insulating interlayer 210 may be formed on a substrate 200 including an impurity region 205. In example embodiments, the impurity region 205 may include n-type impurities/dopants. The first insulating interlayer 210 may be formed using an oxide, a nitride, an oxynitride, etc. The first insulating interlayer 210 may be obtained by a CVD process, a PECVD process, a spin coating process, a HDP-CVD process, for example.

Referring to FIG. 12, processes may be performed to form first contact holes 215 exposing the impurity region 205. In example embodiments, first line patterns (not illustrated) extending in a first direction and first spacers (not illustrated) filling spaces between the adjacent first line patterns may be formed on the first insulating interlayer 210. Second line patterns (not illustrated) extending in a second direction substantially perpendicular to the first direction may be formed on the first line patterns and the first spacers. The first spacers exposed between the first and second line patterns may be removed by a wet etching process, and then the first insulating interlayer 210 may be etched by a dry etching process to form the contact holes 215. The first and second line patterns may be removed using an aching process or a strip process, for example.

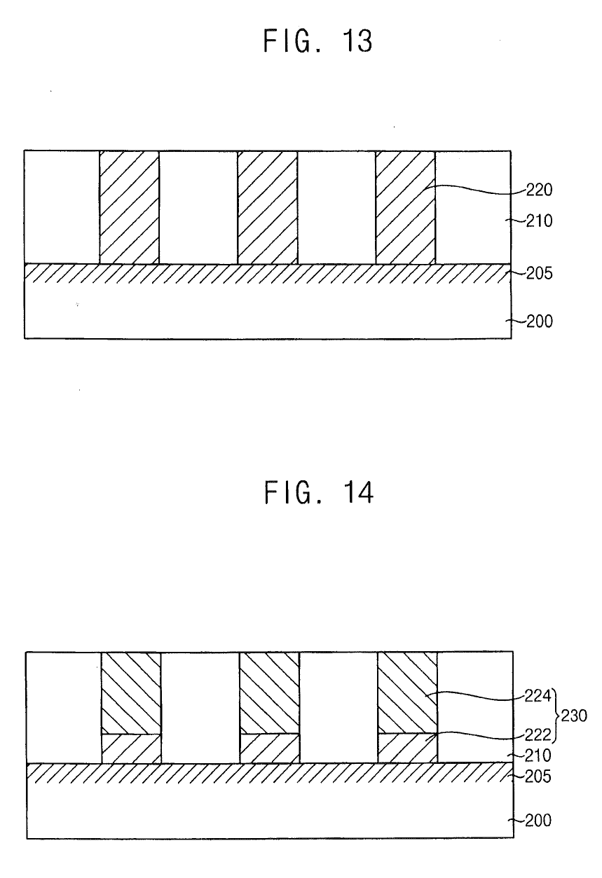

Referring to FIG. 13, a conductive layer pattern 220 filling each of the first contact holes 215 may be formed. For example, a conductive layer sufficiently filling the first contact holes 215 may be formed by a selective epitaxial growth (SEG) process using the impurity region 205 as a seed. An upper portion of the conductive layer may be planarized until a top surface of the first insulating interlayer 210 is exposed to form a conductive layer pattern 220 within each contact hole 215. Alternatively, a polysilicon layer sufficiently filling the first contact holes 215 may be formed on the impurity region 205 and the first insulating interlayer 210, and then the polysilicon layer may be partially planarized to form the conductive layer patterns 220.

In some example embodiments, the conductive layer patterns 220 may only partially fill the first contact holes 215.

Referring to FIG. 14, impurities may be implanted in the conductive layer patterns 220 to thereby form first conductive patterns 222 and second conductive patterns 224 in each of the first contact holes 215. In particular, n-type impurities may be implanted into the conductive layer patterns 220 to form N-type first conductive patterns 222, and then p-type impurities may be implanted in an upper portion of the conductive layer patterns 220 to form P-type second conductive patterns 224. Accordingly, P-N diodes 230, which include corresponding first and second conductive patterns 222 and 224, may be obtained in the first contact holes 215.

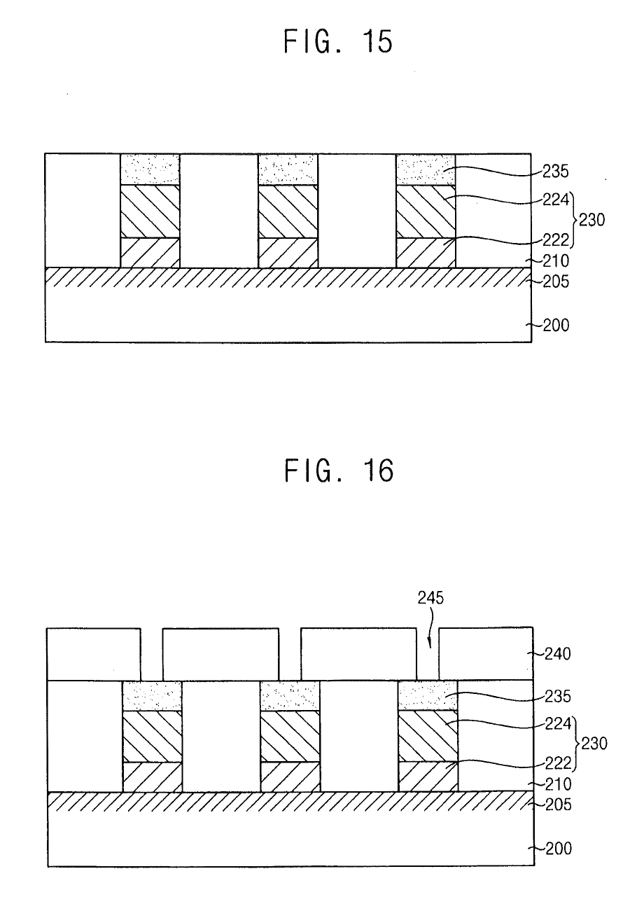

Referring to FIG. 15, a silicidation process may be performed to form silicide patterns 235 at upper portions of the P-N diodes 230 by converting respective portions of the P-type second conductive patterns 224 into silicide regions. As shown by FIG. 16, a second insulating interlayer 240 may be formed on the first insulating interlayer 210 and on the silicide patterns 235. The second insulating interlayer 240 may be partially etched to form second contact holes 245, which may partially expose top surfaces of the silicide patterns 235. The second contact holes 245 may be formed using a processes substantially the same as or similar to those illustrated with reference to FIGS. 1 to 10. Thus, detailed descriptions thereof are omitted herein.

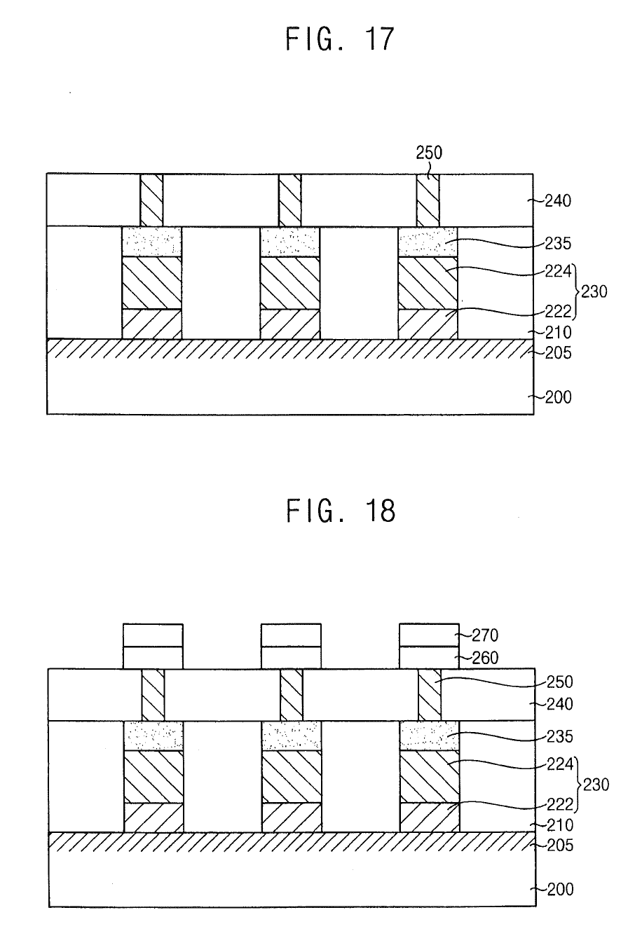

Referring to FIG. 17, a heating contact 250 filling the second contact hole 245 may be formed on the silicide pattern 235. The heating contact 250 may generate Joule heat so that the Joule heat may be transferred to a phase change layer pattern 260 formed by a subsequent process. The heating contact 250 may be formed using a material having large thermal and electrical resistance, for example, tungsten oxide. Referring now to FIG. 18, a phase change layer and an upper electrode layer may be successively formed on the second insulating interlayer 240 and the heating contact 250. The phase change layer and the upper electrode layer may be patterned to form the phase change layer pattern 260 and an upper electrode 270. In example embodiments, the phase change layer may be formed using a phase change material (e.g., GeSbSe, SbSe, GeSbTe, SbTe and GeSb). The phase change layer may be formed using a physical vapor deposition (PVD) process or a sputtering process. The upper electrode layer may be formed using a metal, a metal nitride, a metal silicide, for example. The upper electrode layer may be formed using a CVD process, an ALD process, and a sputtering process.

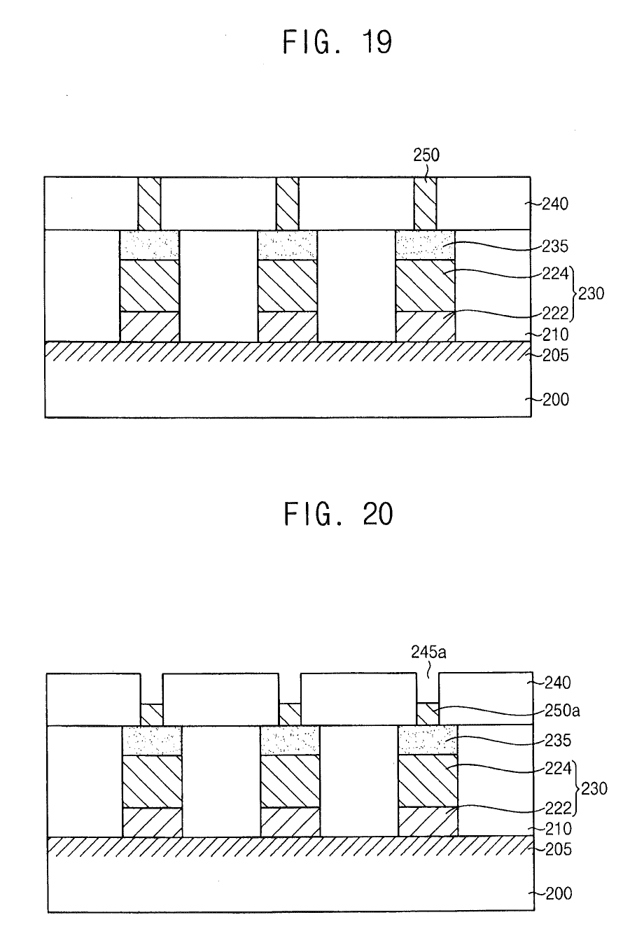

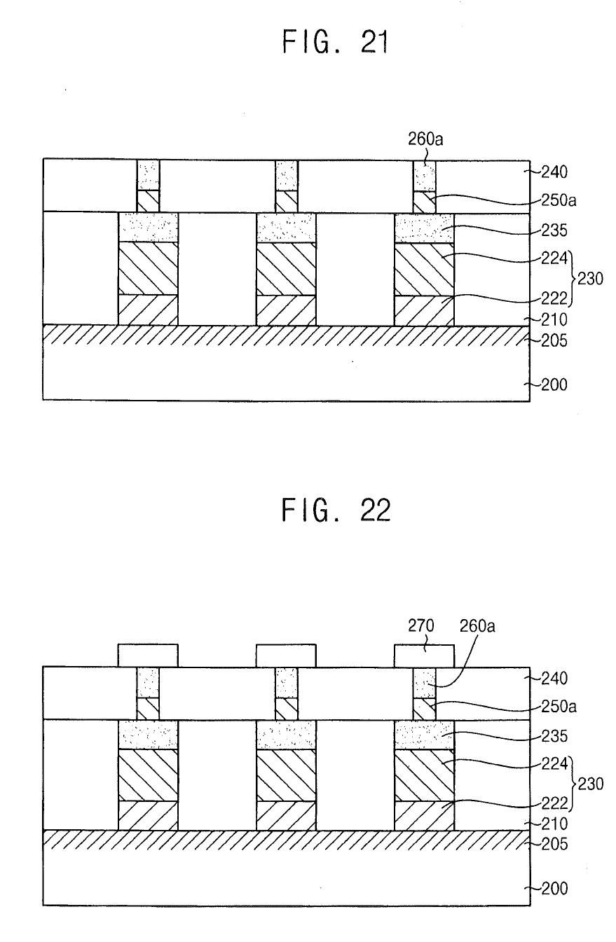

FIGS. 19-22 are cross-sectional views illustrating methods of manufacturing semiconductor devices in accordance with some example embodiments of the invention. Referring to FIG. 19, processes substantially the same as or similar to those illustrated with reference to FIGS. 11 to 17 may be performed to form a P-N diode 230 and a heating contact 250 electrically connected to the P-N diode 230. Referring to FIG. 20, an upper portion of the heating contact 250 may be selectively removed using a wet etching process or a dry etching process to form a heating contact pattern 250a and a third contact hole 245a. Referring to FIG. 21, a phase change layer pattern 260a may be formed on the heating contact pattern 250a. The phase change layer pattern 260a may fill the third contact hole 245a. The phase change layer may be formed on the second insulating interlayer 240 and the heating contact pattern 250a to sufficiently fill the third contact hole 245a. The phase change layer may be formed using a phase change material (e.g., GeSbSe, SbSe, GeSbTe, SbTe, and GeSb). An upper portion of the phase change layer may be planarized until a top surface of the second insulating interlayer 240 is exposed, to thereby form the phase change layer pattern 260a.

Referring to FIG. 22, an upper electrode layer may be formed on the second insulating interlayer 240 and the phase change layer pattern 260a, and then the upper electrode layer may be patterned to form an upper electrode 270. The upper electrode layer may be formed as a polysilicon, metal, metal nitride or a metal silicide layer and combinations thereof. The upper electrode layer may be formed using a CVD process, an ALD process, and a sputtering process, for example. According to some embodiments of the invention, to reduce a contact area between the phase change layer pattern 260a and the heating contact pattern 250a, a spacer (not illustrated) may be further formed on an inner sidewall of the third contact hole 245a.

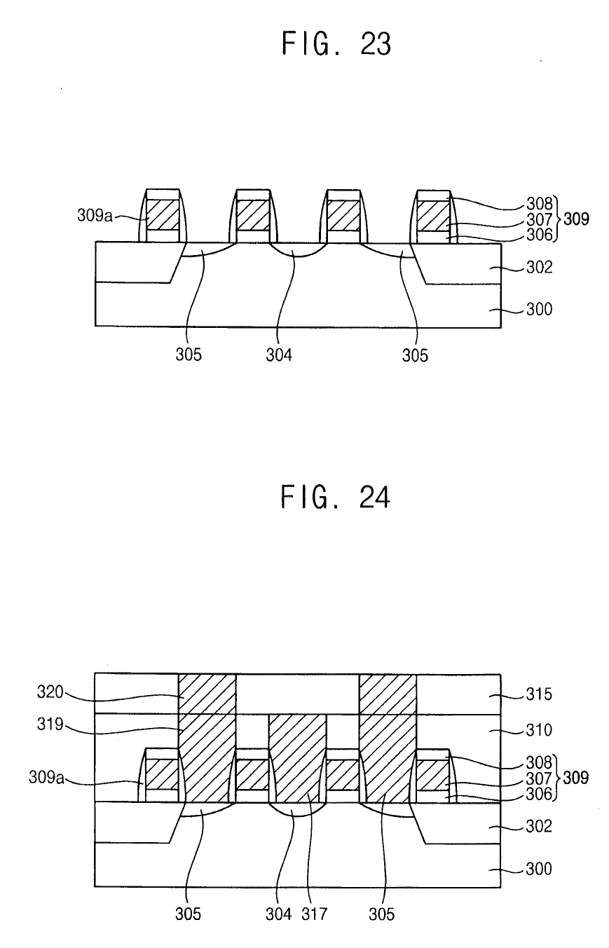

FIGS. 23 to 26 are cross-sectional views illustrating a method of manufacturing a semiconductor device in accordance with example embodiments. Specifically, FIGS. 23 to 26 are cross-sectional views illustrating a method of manufacturing a dynamic random access memory (DRAM) device. Referring to FIG. 23, an isolation layer 302 may be formed on a substrate 300. For example, the isolation layer 302 may be formed by a shallow trench isolation (STI) process. A gate insulation layer, a gate electrode layer and a gate mask layer may be sequentially formed on the substrate 300. The gate mask layer, the gate electrode layer and the gate insulation layer may be patterned using a photolithography process to form a plurality of gate structures 309. Each of the gate structures 309 may include a gate insulation layer pattern 306, a gate electrode 307 and a gate mask/capping layer 308 sequentially stacked on the substrate 300. The gate insulation layer may be formed using silicon oxide or a metal oxide. The gate electrode layer may be formed using doped polysilicon, a metal or a metal nitride. The gate mask layer may be formed using an electrical insulator such as silicon nitride.

An ion-implantation process may be performed using the gate structures 309 as an ion-implantation mask to form first and second impurity regions 304 and 305 at upper portions of the substrate 300 adjacent to the gate structures 309. The first and second impurity regions 304 and 305 may serve as source and drain regions of a transistor. The gate structure 309 and impurity regions 304 and 305 may form the transistor. A sidewall spacer 309a may be formed on a sidewall of the gate structure 309.

Referring to FIG. 24, a first insulating interlayer 310 covering the gate structure 309 and the spacer 309a may be formed on the substrate 300. The first insulating interlayer 310 may be partially etched to form first holes (not illustrated) exposing the impurity regions 304 and 305. The first holes may be formed by processes substantially the same as or similar to those illustrated with reference to FIGS. 1 to 10. Thus, detailed descriptions thereof are omitted herein. In one example embodiment, the first hole may be self-aligned to the gate structure 309 and the sidewall spacer 309a.

A first conductive layer filling the first contact holes may be formed on the substrate 300 and the first insulating interlayer 310. The first conductive layer may be partially planarized by a CMP process and/or an etch back process until a top surface of the first insulating interlayer 310 is exposed to form a first plug 317 and a second plug 319 in the first holes. The first plug 317 may make contact with the first impurity region 304 and the second plug 319 may make contact with the second impurity region 305. The first conductive layer may be formed using doped polysilicon, a metal and/or a metal nitride, for example. The first plug 317 may serve as a bit line contact. A second conductive layer (not illustrated) contacting the first plug 317 may be formed on the first insulating interlayer 310, and then may be patterned to form a bit line (not illustrated). The second conductive layer may be formed using doped polysilicon, a metal, and/or a metal nitride, for example.

A second insulating interlayer 315 covering the bit line may be formed on the first insulating interlayer 310. The second insulating interlayer 315 may be partially etched to form second holes exposing the second plugs 319. The second holes may be formed by processes substantially the same as or similar to those illustrated with reference to FIGS. 1 to 10. A third conductive layer filling the second holes may be formed on the second plugs 319 and the second insulating interlayer 315. An upper portion of the third conductive layer may be planarized by a CMP process and/or an etch-back process until a top surface of the second insulating interlayer 315 is exposed to form third plugs 320 in the second holes. The third conductive layer may be formed as a doped polysilicon layer, a metal layer and/or a metal nitride layer. The stack of second and third plugs 319 and 320 may serve as capacitor contacts. Alternatively, the third plug 320 may be formed through the first and second insulating interlayers 310 and 315 to make direct contact with the second impurity region 305 without the second plug 319, such that the third plug 320 may serve solely as a capacitor contact.

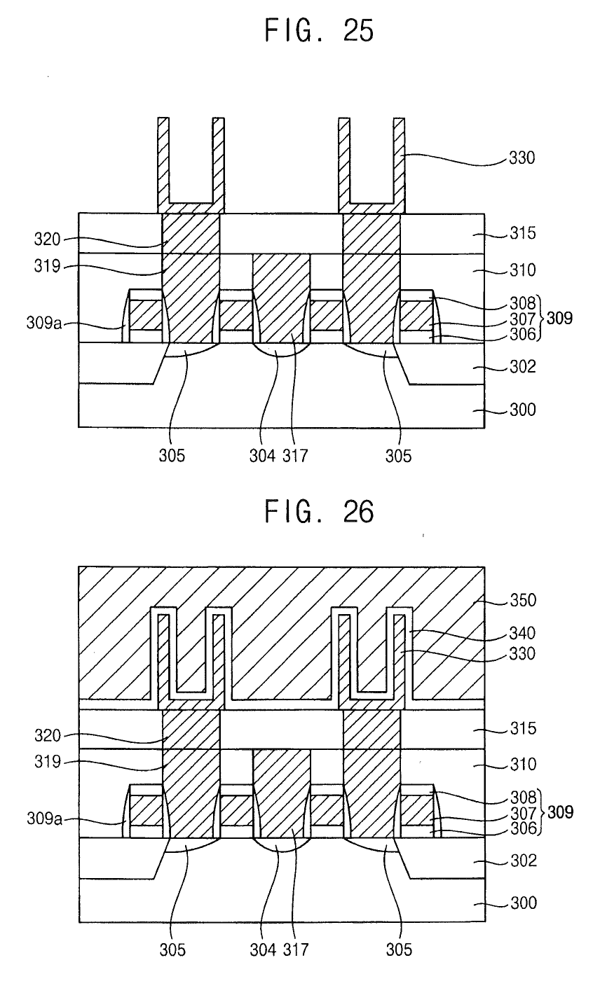

Referring to FIG. 25, an etch-stop layer (not illustrated) and a mold layer (not illustrated) may be formed on the second insulating interlayer 315. The mold layer and the etch-stop layer may be partially removed to form an opening (not illustrated) that exposes a top surface of the third plug 320. A lower electrode layer may be formed on an inner wall of the opening and a top surface of the mold layer. The lower electrode layer may be formed as a metal layer, a metal nitride layer, such as titanium, titanium nitride, tantalum, tantalum nitride, tungsten nitride, or a doped polysilicon layer. A sacrificial layer (not illustrated) may be formed on the lower electrode layer, and then the sacrificial layer and the lower electrode layer may be partially removed to expose the top surface of the mold layer. The sacrificial layer and the mold layer may be removed to form a lower electrode 330 electrically connected to the third plug 320.

Referring to FIG. 26, a dielectric layer 340 may be formed on the etch-stop layer and the second insulating interlayer 315 to cover the lower electrode 330. The dielectric layer 330 may be formed using a material having a higher dielectric constant than that of silicon nitride or silicon oxide. An upper electrode 350 may be formed on the dielectric layer 340. The upper electrode 350 may be formed using a metal and/or a metal nitride material, such as titanium nitride, tantalum nitride, tungsten nitride, ruthenium. Accordingly, a capacitor including the lower electrode 330, the dielectric layer 340 and the upper electrode 350 may be obtained.

The method of forming a pattern according to example embodiments may be utilized to form a contact hole having a high aspect ratio. In the method, an etching mask may be formed in a self-aligned manner and the contact hole may be formed by performing both a wet etching process and a dry etching process, so that damages to the etching mask may be prevented. The method may be utilized to form various contact holes having very small line widths and high aspect ratios, that may be utilized within a phase change memory device, a DRAM device, a flash memory device, for example.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming a pattern, comprising:
forming a plurality of first line patterns and first spacers filling spaces between the adjacent first line patterns on an object layer, the first line patterns and the first spacers extending in a first direction;
forming a plurality of second line patterns on the first line patterns and the first spacers, the second line patterns extending in a second direction substantially perpendicular to the first direction;
at least partially removing the first spacers by a wet etching process; and
etching the object layer using the first and second line patterns as an etching mask.

2. The method of claim 1, wherein the first and second line patterns are formed using polysilicon.

3. The method of claim 1, wherein the first spacers are formed using silicon oxide.

4. The method of claim 1, wherein etching the object layer is performed by a dry etching process.

5. The method of claim 1, wherein the first line patterns include first polysilicon patterns and second polysilicon patterns extending in the first direction.

6. The method of claim 5, wherein forming the first line patterns includes:
forming a plurality of the first polysilicon patterns extending in the first direction on the object layer;
forming the first spacers on sidewalls of the first polysilicon patterns; and
forming the second polysilicon patterns on the object layer, the second polysilicon patterns filling spaces between the adjacent first spacers.

7. The method of claim 6, wherein the second polysilicon patterns are self-aligned with the first spacers.

8. The method of claim 6, wherein the first polysilicon pattern, the first spacer and the second polysilicon pattern have the same line width as one another.

9. The method of claim 1, wherein forming the second line patterns includes:
forming a plurality of first polysilicon patterns extending in the first direction on the object layer;
forming the first spacers on sidewalls of the first polysilicon patterns;
forming a second polysilicon layer on the first polysilicon patterns, the first spacers and the object layer, the second polysilicon layer filling spaces between the adjacent first spacers; and
etching the second polysilicon layer to form the second line patterns extending in the second direction.

10. The method of claim 9, wherein etching the second polysilicon layer to form the second line patterns includes:
forming a plurality of mask patterns on the second polysilicon layer, the mask patterns extending in the second direction;
forming second spacers on sidewalls of the mask patterns;
removing the mask patterns; and
etching the second polysilicon layer using the second spacers as an etching mask until the first spacers are exposed.

11. The method of claim 10, wherein the mask pattern, the second spacer and the second line pattern have the same line width as one another.

12. The method of claim 10, wherein the mask pattern includes silicon-based spin on hard mask (Si-SOH).

13. A method of manufacturing a semiconductor device, comprising:
forming a first insulating interlayer on a substrate including an impurity region;
partially etching the first insulating interlayer to form a plurality of first contact holes;
forming a P-N diode filling each of the first contact holes,
wherein forming the first contact holes includes:
forming a plurality of first line patterns and first spacers filling spaces between the adjacent first line patterns on the first insulating interlayer, the first line patterns and the first spacers extending in a first direction;
forming a plurality of second line patterns on the first line patterns and the first spacers, the second line patterns extending in a second direction substantially perpendicular to the first direction;
at least partially removing the first spacers by a wet etching process; and
partially etching the first insulating interlayer using the first and second line patterns as an etching mask.

14. The method of claim 13, further comprising:
forming a second insulating interlayer on the first insulating interlayer and the P-N diode;
partially etching the second insulating interlayer to form a plurality of second contact holes, each of the second contact holes exposing the P-N diode;
forming a heating contact filling the second contact hole; and
forming a phase change layer pattern and an upper electrode sequentially on the heating contact and the second insulating interlayer,
wherein forming the second contact holes includes:
forming a plurality of third line patterns and second spacers filling spaces between the adjacent third line patterns on the second insulating interlayer, the third line patterns and the second spacers extending in a third direction;
forming a plurality of fourth line patterns on the third line patterns and the second spacers, the fourth line patterns extending in a fourth direction substantially perpendicular to the third direction;
at least partially removing the second spacers by a wet etching process; and
partially etching the second insulating interlayer using the third and fourth line patterns as an etching mask.

15. The method of claim 13, wherein the first and second line patterns are formed using polysilicon, and the first spacers are formed using silicon oxide.

16. A method of forming a semiconductor device, comprising:
forming a first plurality of stripe-shaped line patterns at side-by-side locations on an insulating interlayer;
forming first stripe-shaped spacers on opposing sidewalls of the first plurality of stripe-shaped line patterns, the first stripe-shaped spacers filling spaces between the first plurality of stripe-shaped line patterns;
forming a second plurality of stripe-shaped line patterns at side-by-side locations on the first plurality of stripe-shaped line patterns and the first stripe-shaped spacers, the second plurality of stripe-shaped line patterns extending in a direction orthogonal to a direction of the first plurality of stripe-shaped line patterns and the first stripe-shaped spacers;
removing portions of the first stripe-shaped spacers exposed between the first and second pluralities of stripe-shaped line patterns by a wet etching process to thereby expose portions of the insulating interlayer; and
forming contact openings in the insulating interlayer by selectively etching the insulating interlayer using the first and second pluralities of stripe-shaped line patterns as an etching mask.

17. The method of claim 16, wherein the first and second pluralities of stripe-shaped line patterns comprise polysilicon.

18. The method of claim 16, wherein forming the contact openings comprises forming a two-dimensional array of equivalently sized contact openings in the insulating interlayer.

19. The method of claim 16, wherein the semiconductor device is a nonvolatile memory device comprising phase change memory cells therein; and wherein forming the first plurality of stripe-shaped line patterns is preceded by forming the insulating interlayer on an underlying insulation layer having an array of P-N junction diodes therein.

20. The method of claim 19, wherein the array of P-N junction diodes is formed by epitaxially growing semiconductor regions within openings in the underlying insulation layer.
